(19) United States
(12) Patent Application Publication
(10) Pub. No.: US 2024/0297222 A1
(43) Pub. Date: Sep. 5, 2024

(54) SiC EPITAXIAL WAFER

(71) Applicant: Resonac Corporation, Tokyo (JP)

(72) Inventors: Yoshitaka Nishihara, Tokyo (JP); Tsubasa Shiono, Tokyo (JP)

(73) Assignee: Resonac Corporation, Tokyo (JP)

(21) Appl. No.: 18/394,568

(22) Filed: Dec. 22, 2023

(30) Foreign Application Priority Data
Dec. 28, 2022 (JP) 2022-211619

(51) Int. Cl. H01L 29/16; H01L 21/02

(52) U.S. Cl. CPC H01L 29/1608; H01L 21/02304; H01L 21/02378; H01L 21/02529

(57) ABSTRACT

A SiC epitaxial wafer according to the present embodiment includes a SiC wafer and a SiC epitaxial layer on one surface of the SiC wafer. The SiC epitaxial layer has a buffer layer and a drift layer. The buffer layer is disposed between the drift layer and the SiC wafer, and has a higher impurity concentration than the drift layer. Among basal plane dislocations, the number of first basal plane dislocations that extend from an interface between the SiC wafer and the SiC epitaxial layer into the buffer layer and have a length of 1 μm or less is 20 or less. The SiC epitaxial wafer has a diameter of 149 mm or more.

### BACKGROUND OF THE INVENTION

### Field of the Invention

The present invention relates to a SiC epitaxial wafer. Priority is claimed on Japanese Patent Application No. 2022-211619, filed Dec. 28, 2022, the contents of which are incorporated herein by reference.

### Description of Related Art

Compared to silicon (Si), silicon carbide (SiC) has an insulation breakdown electric field that is one order of magnitude larger and a band gap which is three times thereof. In addition, silicon carbide (SiC) has characteristics such as a thermal conductivity that is about three times that of silicon (Si). Therefore, silicon carbide (SiC) is expected to be able to be applied to power devices, high frequency devices, high temperature operation devices, and the like. Therefore, in recent years, SiC epitaxial wafers have been used for semiconductor devices such as those mentioned above.

A SiC epitaxial wafer is obtained by laminating a SiC epitaxial layer on a surface of a SiC wafer. Hereinafter, a wafer before thr SiC epitaxial layer is laminated will be referred to as the SiC wafer, and a wafer after the SiC epitaxial layer is laminated will be referred to as the SiC epitaxial wafer. The SiC wafer is cut out from a SiC ingot.

In SiC epitaxial wafers, as one of device killer defects that cause fatal defects in SiC devices, a basal plane dislocation (BPD) is known. For example, when a current is applied to a bipolar device in a forward direction, the recombination energy of flowing carriers causes partial dislocation of basal plane dislocations inherited from the SiC wafer by the SiC epitaxial layer to move and expand, and a high-resistance stacking fault is formed. The high-resistant part generated in the device causes a decrease in device reliability (forward direction deterioration).

Studies are being performed to reduce basal plane dislocations inherited from the SiC wafer to the SiC epitaxial layer. For example, Patent Document 1 and Patent Document 2 describe a SiC epitaxial wafer production method in which basal plane dislocations are not included in the SiC epitaxial layer.

In addition, a method of evaluating basal plane dislocations has been focused on. Patent Document 3 to Patent Document 5 disclose a method of measuring basal plane dislocations.

### PATENT DOCUMENTS

[Patent Document 1] Japanese Unexamined Patent Application, First Publication No. 2018-199595
[Patent Document 2] Japanese Unexamined Patent Application, First Publication No. 2018-113303
[Patent Document 3] Japanese Unexamined Patent Application, First Publication No. 2021-88469
[Patent Document 4] Japanese Patent No. 6986944
[Patent Document 5] Japanese Patent No. 6037673

### SUMMARY OF THE INVENTION

When basal plane dislocations are converted into threading edge dislocations (TEDs) within a buffer layer, basal plane dislocations with short lengths may be present in the buffer layer. The basal plane dislocations may cause stacking faults when a high voltage is applied to a drift layer. However, the basal plane dislocations with short lengths in the buffer layer could not be inspected by the methods described in Patent Documents 1 to 5. Therefore, in Patent Documents 1 to 5, even if it is described that the basal plane dislocation density is 0, there is a high likelihood of the basal plane dislocations with short lengths described above being overlooked. Accordingly, since basal plane dislocations with short lengths have not been sufficiently detected, an attempt to reduce them has not been sufficiently studied.

The present invention has been made in view of the above circumstances, and an object of the present invention is to provide a SiC epitaxial wafer with a small number of basal plane dislocations in the SiC epitaxial layer.

The present disclosure provides the following aspects in order to address the above problems.
(1) A SiC epitaxial wafer according to a first aspect includes a SiC wafer and a SiC epitaxial layer on one surface of the SiC wafer. The SiC epitaxial layer has a buffer layer and a drift layer. The buffer layer is disposed between the drift layer and the SiC wafer, and has a higher impurity concentration than the drift layer. Among basal plane dislocations, the number of first basal plane dislocations having a height of 1 μm or less in a thickness direction from an interface between the SiC wafer and the SiC epitaxial layer is 20 or less. The SiC epitaxial wafer has a diameter of 149 mm or more.
(2) A SiC epitaxial wafer according to a second aspect includes a SiC wafer and a SiC epitaxial layer on one surface of the SiC wafer. The SiC epitaxial layer has a buffer layer and a drift layer. The buffer layer is disposed between the drift layer and the SiC wafer, and has a higher impurity concentration than the drift layer. Among basal plane dislocations, the number of first basal plane dislocations having a height of 1 μm or less in a thickness direction from an interface between the SiC wafer and the SiC epitaxial layer is 35 or less. The SiC epitaxial wafer has a diameter of 199 mm or more.
(3) In the SiC epitaxial wafer according to the above aspect, when a measurement region excluding an exclusion region within 5 mm from the outer circumference of the SiC epitaxial layer is divided into 5 mm squares, the number of first basal plane dislocations may be less than 3 in 98% or more of the entire divided area.
(4) In the SiC epitaxial wafer according to the above aspect, the buffer layer may have an impurity concentration of 5.0×10¹⁷ cm⁻³ or more.

In the SiC epitaxial wafer according to the above aspect, the number of basal plane dislocations in the SiC epitaxial layer is small.

### BRIEF DESCRIPTION OF THE DRAWINGS

FIG. 1 is a cross-sectional view of a SiC epitaxial wafer according to a first embodiment.

FIG. 2 is a diagram showing a state of basal plane dislocations at the interface between a SiC wafer and a SiC epitaxial layer.

FIG. 3 shows the results obtained by measuring a SiC layer having an impurity concentration corresponding to a buffer layer using a near-ultraviolet (NUV) filter.

FIG. 4 shows the results obtained by measuring a SiC layer having an impurity concentration corresponding to a buffer layer using a high magnification PL.

FIG. 5 is a diagram for illustrating the relationship between the height of the basal plane dislocation and the length of the basal plane dislocation.

FIG. 6 is a diagram for illustrating a method of measuring the number of basal plane dislocations or first basal plane dislocations according to the present embodiment.

FIG. 7 shows the measurement results of basal plane dislocations of Reference Example 1.

FIG. 8 is a diagram showing the distribution of basal plane dislocations in a SiC epitaxial wafer of Comparative Example 2.

FIG. 9 is a diagram showing the distribution of basal plane dislocations in a SiC epitaxial wafer of Reference Example 1.

FIG. 10 is a diagram showing the distribution of basal plane dislocations in a SiC epitaxial wafer measured by a photoluminescence method using an NIR filter.

FIG. 11 is a diagram showing the distribution of basal plane dislocations in a SiC epitaxial wafer measured by a photoluminescence method using an NUV filter.

### DETAILED DESCRIPTION OF THE INVENTION

Hereinafter, the present embodiment will be appropriately described in detail with reference to the drawings. In the drawings used in the following description, in order to facilitate understanding of features of the present embodiment, characteristic parts are enlarged for convenience of illustration in some cases, and the dimensional proportions of components may be different from actual components. Materials, sizes and the like exemplified in the following descriptions are examples, the present invention is not limited thereto, and can be appropriately changed and implemented within ranges without changing the scope and spirit of the invention.

First, directions are defined. One direction within the plane in which the SiC wafer spreads is defined as an x direction and a direction perpendicular to the x direction within the same plane is defined as a y direction. The x direction is, for example, the <11-20> direction. The y direction is, for example, the <1-100> direction. The z direction is a direction orthogonal to the SiC wafer and is perpendicular to the x direction and the y direction. The z direction matches the thickness direction of the SiC wafer.

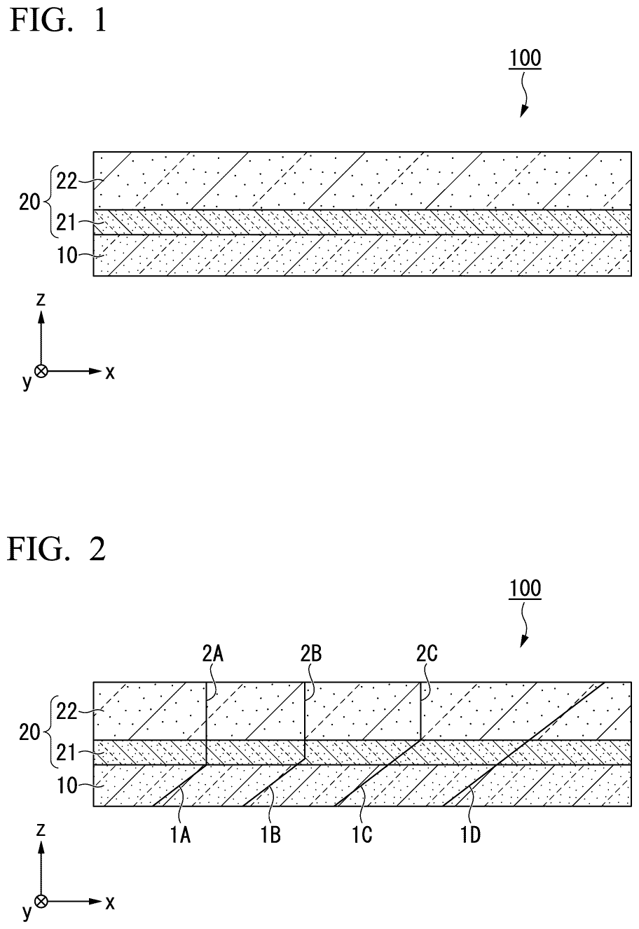

FIG. 1 is a cross-sectional view of a SiC epitaxial wafer 100 according to a first embodiment. The SiC epitaxial wafer 100 has a SiC wafer 10 and a SiC epitaxial layer 20.

The SiC wafer 10 is made of SiC. The crystal structure of SiC may be any selected from among 4H, 6H, 3C, and 15R. The SiC wafer 10 may be an n type, p type or semi-insulating wafer. The SiC wafer 10 is, for example, an n type-SiC wafer doped with nitrogen as impurities. The nitrogen concentration of the SiC wafer 10 is, for example, 1.0×10¹⁸ cm⁻³ or more and 2.0×10¹⁹ cm⁻³ or less.

In addition, the SiC wafer 10 may be an offset wafer. The offset wafer is a wafer whose crystal surface is inclined with respect to the surface of the SiC wafer 10. The angle between the crystal surface and the surface is called an offset angle. The offset angle θ is, for example, 0.5° or more and 10° or less.

The shape of the SiC wafer 10 in a plan view is a substantially circular shape. The SiC wafer 10 may have an orientation flat OF or a notch for determining the direction of the crystal axis.

The diameter of the SiC wafer 10 is not particularly limited. The diameter of the SiC wafer 10 is, for example, 140 mm or more. The diameter of the SiC wafer 10 may be, for example, 149 mm or more and 151 mm or less. In addition, the diameter of the SiC wafer 10 may be, for example, 190 mm or more and may be 199 mm or more and 201 mm or less. The diameter of the SiC wafer 10 may be, for example, 240 mm or more, 249 mm or more and 251 mm or less, 290 mm or more, or 299 mm or more and 301 mm or less.

The SiC epitaxial layer 20 is in contact with one surface of the SiC wafer 10. The SiC epitaxial layer 20 is laminated on one surface of the SiC wafer 10, over the entire surface.

The SiC epitaxial layer 20 includes a buffer layer 21 and a drift layer 22. The buffer layer 21 is disposed between the drift layer 22 and the SiC wafer 10. The buffer layer 21 is formed on the SiC wafer 10, and the drift layer 22 is formed on the buffer layer 21.

The impurity concentration of the buffer layer 21 is higher than the impurity concentration of the drift layer 22. The impurity concentration is an average value of the measurement results at measurement points arranged at 10 cm intervals along a line passing through the center. The impurity concentration can be measured by a mercury probe (Hg-CV) method or secondary-ion mass spectrometry (SIMS).

The impurity concentration of the buffer layer 21 is, for example, 5×10¹⁷/cm³ or more, and preferably 1×10¹⁸/cm³ or more. The impurity concentration of the buffer layer 21 is, for example, 2×10¹⁹/cm³ or less.

The buffer layer 21 is a layer for converting basal plane dislocations present in the SiC wafer into threading edge dislocations (TEDs). In addition, when a current is applied to a bipolar device having basal plane dislocations in a forward direction, the buffer layer 21 also has a function of preventing minority carriers from reaching basal plane dislocations present in the SiC wafer 10. The buffer layer 21 prevents Shockley type stacking faults from being formed in the SiC epitaxial layer 20 and the faults from expanding.

The thickness of the buffer layer 21 is, for example, 0.1 μm or more, preferably 1 μm or more, and more preferably 3 μm or more. The thickness of the buffer layer 21 is, for example, 10 μm or less.

The drift layer 22 is a layer through which a drift current flows and which functions as a device. The drift current is a current generated by a flow of carriers when a voltage is applied to a semiconductor.

The impurity concentration of the drift layer 22 is, for example, 1×10¹⁴ cm⁻³ or more. The impurity concentration of the drift layer 22 is, for example, 1×10¹⁸ cm⁻³ or less. The impurity concentration of the drift layer 22 is preferably 1×10¹⁵ cm⁻³ or more and 1×10¹⁷ cm⁻³ or less. The thickness of the drift layer 22 is, for example, 5 μm or more.

The SiC epitaxial wafer 100 has basal plane dislocations. There are several patterns of extension of basal plane dislocations that may occur in the SiC epitaxial wafer 100. FIG. 2 is a diagram showing a state of basal plane dislocations at the interface between the SiC wafer 10 and the SiC epitaxial layer 20.

The first pattern is a pattern in which, when the SiC epitaxial layer 20 is formed, a basal plane dislocation 1A in the SiC wafer 10 is converted into a threading edge dislocation 2A at the interface between the SiC wafer 10 and the SiC epitaxial layer 20.

The second pattern is a pattern in which, when the SiC epitaxial layer 20 is formed, a basal plane dislocation 1B inherited from the SiC wafer 10 into the buffer layer 21 is converted into a threading edge dislocation 2B within the buffer layer 21.

The third pattern is a pattern in which, when the SiC epitaxial layer 20 is formed, a basal plane dislocation 1C inherited from the SiC wafer 10 into the buffer layer 21 is converted into a threading edge dislocation 2C at the interface between the buffer layer 21 and the drift layer 22.

The fourth pattern is a pattern in which, when the SiC epitaxial layer 20 is formed, a basal plane dislocation 1D is directly inherited from the inside of the SiC wafer 10 into the epitaxial layer 20.

In the SiC wafer 10, basal plane dislocations are present along the (0001) plane (c plane). The number of basal plane dislocations exposed on the growth surface of the SiC wafer 10 is preferably small, but it is not particularly limited. For example, the number of basal plane dislocations present on the surface (growth surface) of the 6-inch SiC wafer is 1 or more and 5,000 or less per 1 cm².

95% or more of basal plane dislocations in the SiC wafer 10 can be converted into threading edge dislocations in the first pattern. In addition, when growth conditions for the SiC epitaxial layer 20 are adjusted, it is possible to set the proportion of basal plane dislocations that form the fourth pattern to 0.01% or less. On the other hand, there are also basal plane dislocations that form the second pattern and the third pattern at a certain ratio.

In order to identify the basal plane dislocations 1B of the second pattern and the basal plane dislocations 1C of the third pattern, it is necessary to evaluate the basal plane dislocations in the buffer layer 21. As one method of observing basal plane dislocations in the SiC epitaxial layer 20, a photoluminescence method (PL method) is known.

However, when basal plane dislocations in the buffer layer 21 with a high impurity concentration are observed using a PL method, the surrounding light emission becomes stronger than light emission of basal plane dislocations, and it is difficult to identify basal plane dislocations in the buffer layer 21.

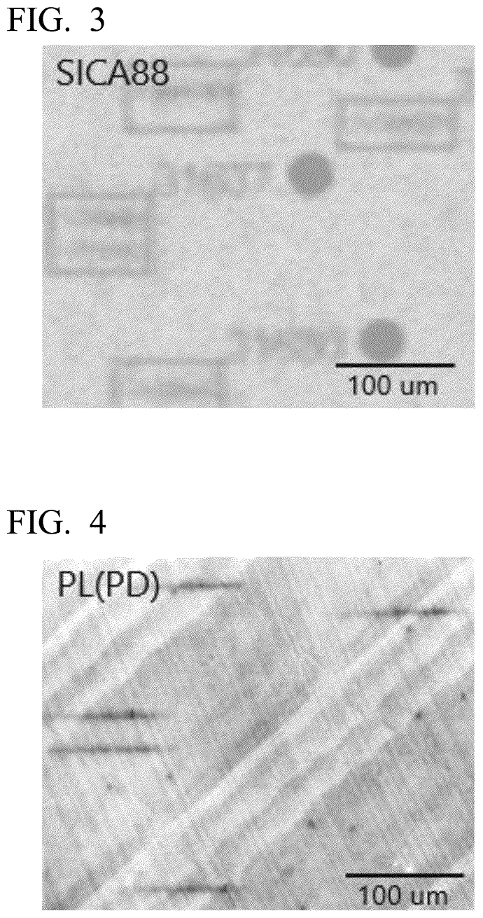

For example, when the filter is changed from a near infrared (NIR) filter to a near-ultraviolet (NUV) filter, it is possible to observe some basal plane dislocations in the buffer layer 21 even when the PL method is used. FIG. 3 shows the results obtained by measuring a SiC layer having an impurity concentration corresponding to a buffer layer using a near-ultraviolet (NUV) filter. Basal plane dislocations are observed in the region surrounded by a rectangle in FIG. 3. As shown in FIG. 3, in this method, a resolution sufficient for evaluating short basal plane dislocations is not obtained. That is, even when an NUV filter is used, if the lengths of the basal plane dislocations are short (for example, the basal plane dislocation 1B of the second pattern, and the basal plane dislocation of the third pattern when the thickness of the buffer layer 21 is thin), it is difficult to distinguish them from other defects and dislocations.

In addition, FIG. 4 shows the results obtained by measuring a SiC layer having an impurity concentration corresponding to a buffer layer using a high magnification PL with an objective lens magnification that is about 2 times higher than a general one. Basal plane dislocations observed using a high magnification PL are more clearly observed than basal plane dislocations imaged using a near-ultraviolet (NUV) filter. The length of the basal plane dislocations imaged in FIG. 4 is 90 μm or more and 100 μm or less in many cases. The basal plane dislocations having this length have a height in the thickness direction of 6.3 μm or more and 7 μm or less. The relationship between the length of the basal plane dislocation and the height of the basal plane dislocation in the thickness direction will be described below.

If basal plane dislocations having a height of 0.3 μm in the thickness direction are measured, the lengths of the basal plane dislocations become short and the basal plane dislocations are observed as black spots. Therefore, it is difficult to distinguish basal plane dislocations from other defects and the like, and it is difficult to determine whether there are basal plane dislocations. Due to the above circumstances, in evaluation using the PL method, it is difficult to observe short basal plane dislocations in the buffer layer 21 and sufficient evaluation is not performed. That is, there is still a possibility of the basal plane dislocation 1B of the second pattern and the basal plane dislocation 1C of the third pattern being overlooked.

In the present embodiment, the SiC epitaxial layer 20 is evaluated using a mirror electron microscope (a mirror electron projection microscope). The mirror electron microscope is, for example, a mirror electron inspection system (Mirelis VM1000, commercially available from Hitachi High-Tech Corporation). The mirror electron microscope uses its optical system to capture a change in potential from an electron beam that is reflected on a potential surface directly above a sample without exposing the sample to an incident electron beam, and observes faults and dislocations.

When the mirror electron microscope is used, basal plane dislocations in the buffer layer 21 can also be observed. In addition, under the mirror electron microscope, basal plane dislocations with short lengths can also be observed.

For example, when the mirror electron microscope is used, basal plane dislocations having a height of 1 μm or less in the thickness direction from the interface between the SiC wafer 10 and the SiC epitaxial layer 20 can also be observed. Hereinafter, a basal plane dislocation having a height of 1 μm or less in the thickness direction from the interface between the SiC wafer 10 and the SiC epitaxial layer 20 will be referred to as a first basal plane dislocation.

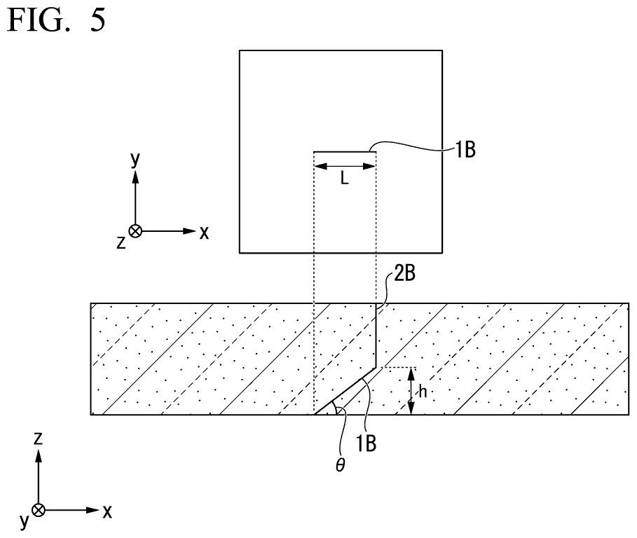

The height of the basal plane dislocation in the thickness direction is determined from the offset angle and the length of the basal plane dislocation measured under a mirror electron microscope. FIG. 5 is a diagram for illustrating the relationship between the height of the basal plane dislocation and the length of the basal plane dislocation. The upper diagram in FIG. 5 is a plan view of the basal plane dislocation measured under a mirror electron microscope, and the lower diagram in FIG. 5 is a cross-sectional view of the basal plane dislocation.

As shown in FIG. 5, the length L of the basal plane dislocation 1B measured under a mirror electron microscope is the length when the basal plane dislocation 1B is projected onto an xy plane. The basal plane dislocations extend along the crystal surface. The basal plane dislocation extends at an offset angle θ with respect to one surface of the wafer. Therefore, the height h of the basal plane dislocation 1B in the thickness direction can be determined as h=L tan θ from the length L of the basal plane dislocation 1B and the offset angle θ. First basal plane dislocations can be classified using a mirror electron microscope, and as described above, they are difficult to detect using the PL method. For example, when the offset angle θ is 4°, the height h of the basal plane dislocation 1B in the thickness direction is 1 μm, and the length L of the basal plane dislocation 1B is about 14 μm.

In the SiC epitaxial layer 20 according to the present embodiment, if the diameter of the SiC epitaxial wafer is 149 mm or more, the number of basal plane dislocations measured during measurement under a mirror electron microscope is 20 or less. In addition, in the SiC epitaxial layer 20 according to the present embodiment, if the diameter of the SiC epitaxial wafer is 199 mm or more, the number of basal plane dislocations measured during measurement under a mirror electron microscope is 35 or less.

In addition, in the SiC epitaxial layer 20 according to the present embodiment, if the diameter of the SiC epitaxial wafer is 149 mm or more, among basal plane dislocations, the number of first basal plane dislocations having a height of 1 μm or less in the thickness direction from the interface between the SiC wafer 10 and the SiC epitaxial layer 20 is 20 or less. In addition, in the SiC epitaxial layer 20 according to the present embodiment, if the diameter of the SiC epitaxial wafer is 199 mm or more, among basal plane dislocations, the number of first basal plane dislocations having a height of 1 μm or less in the thickness direction from the interface between the SiC wafer 10 and the SiC epitaxial layer 20 is 35 or less.

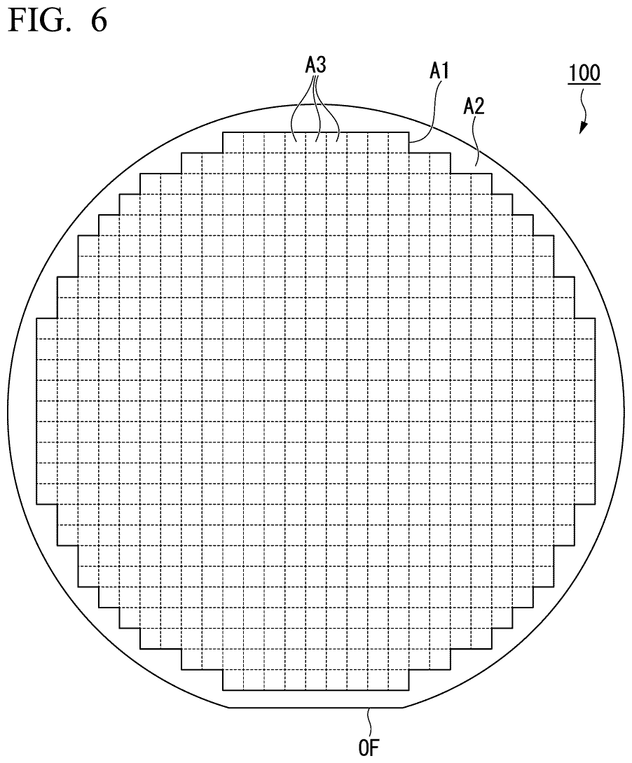

In the present embodiment, the number of basal plane dislocations or first basal plane dislocations is determined by the following procedure. FIG. 6 is a diagram for illustrating a method of measuring the number of basal plane dislocations or first basal plane dislocations according to the present embodiment. First, as shown in FIG. 6, first, the SiC epitaxial wafer 100 is divided into a measurement region A1 and an exclusion region A2. The exclusion region A2 is a region within 5 mm from the outer circumference of the SiC epitaxial layer 20. Then, the measurement region A1 is divided into predetermined sizes. Hereinafter, each divided region will be referred to as a pseudo chip A3. The pseudo chips A3 are evenly spread over the measurement region A1.

The number of basal plane dislocations or first basal plane dislocations is determined by measuring 16 locations on the pseudo chip A3. As the size of the pseudo chip A3 is smaller, the sampled region within the SiC epitaxial layer 20 is larger. On the other hand, as the size of the pseudo chip A3 is smaller, since the time required to measure the number of basal plane dislocations is longer, the throughput becomes worse. As an example, the size of the pseudo chip A3 is 5 mm square. If it is desired to increase the sampling region, the length of one side of the pseudo chip A3 may be set to 2 mm, or if it is desired to improve the throughput, the length of one side of the pseudo chip A3 may be set to 10 mm. If the size of the pseudo chip A3 is 5 mm square, an area of 0.33% of the entire SiC epitaxial wafer is covered as an inspection range. When the area in a range of 0.15% to 0.85% of the entire SiC epitaxial wafer is inspected, the trend of the entire SiC epitaxial wafer can be sufficiently confirmed. In addition, when this procedure is performed instead of inspecting the entire surface of the SiC epitaxial layer 20, wafer mapping can be performed within a realistic time range.

In addition, when the thickness of the drift layer 22 within the SiC epitaxial layer 20 is thick and it is difficult to evaluate the buffer layer 21, the above measurement may be performed after the drift layer 22 is ground and made thin.

In the SiC epitaxial wafer 100, the area (the pseudo chip A3) in which the number of first basal plane dislocations is less than 3 is preferably 98% or more of all areas (the pseudo chips A3).

Next, a method of producing the SiC epitaxial wafer 100 according to the present embodiment will be described.

First, the SiC wafer 10 is prepared. The SiC wafer 10 can be produced by cutting out a SiC ingot produced by a sublimation method.

Next, the SiC epitaxial layer 20 is formed on one surface of the SiC wafer 10 by a chemical vapor deposition (CVD) method. Film formation conditions are set by a preliminary examination.

A preliminary examination of film formation conditions is performed by the following procedure. In a first procedure, the temperature at the initial stage of film formation is determined. The initial stage of growth is a period from the start of growth until the SiC epitaxial layer 20 is laminated to a thickness of 0.5 μm. First, the SiC epitaxial layer 20 is formed under conditions in which the temperature variation width every 5 seconds within the initial growth period is within ±50° C. Then, the distribution of first basal plane dislocations in the SiC epitaxial layer 20 is evaluated. The set temperature increases at locations with a large distribution of first basal plane dislocations, and the set temperature is maintained or reduced at locations with a small distribution of first basal plane dislocations. The set temperature is adjusted in increments of 5° C. By repeatedly changing the set temperature and measuring the distribution of first basal plane dislocations in this manner, and feed-backing the results, optimal temperature conditions at the initial stage of film formation are determined. The temperature range at the initial stage of film formation is 1,500° C. or higher and 1,800° C. or lower. Here, the condition in which the temperature variation width is within +50° C. is set to 5 seconds, but if the growth rate of the SiC epitaxial layer 20 is fast, a shorter time may be set.

Next, in a second procedure, the C/Si ratio at the initial stage of film formation is determined. The C/Si ratio is a ratio of carbon gas to silicon gas in the vicinity of the film to be formed. The SiC epitaxial layer 20 is formed under conditions in which the C/Si ratio every 5 seconds within the initial growth period is within ±0.5. Then, the distribution of first basal plane dislocations in the SiC epitaxial layer 20 is evaluated. The C/Si ratio changes at locations with a large distribution of first basal plane dislocations. The C/Si ratio at each location can be determined by simulation based on growth conditions. For example, the C/Si ratio can be simulated using software called Ansys Fluent. The C/Si ratio may be high or low. The C/Si ratio is adjusted in increments of 0.01. By repeatedly changing the C/Si ratio and measuring the distribution of first basal plane dislocations in this manner, and feed-backing the results, optimal C/Si ratio at the initial stage of film formation is determined. The range of the C/Si ratio at the initial stage of film formation is 0.5 or more and 2.5 or less.

Next, in a third procedure, the growth rate of the SiC epitaxial layer 20 at the initial stage of film formation is determined. The SiC epitaxial layer 20 is formed under conditions in which the variation width of the growth rate every 5 seconds within the initial growth period is within ±20 μm/h. Then, the distribution of first basal plane dislocations in the SiC epitaxial layer 20 is evaluated. At locations with a large distribution of first basal plane dislocations, the growth rate increases. The growth rate can be increased by increasing a gas flow rate. By repeatedly changing the growth rate and measuring the distribution of first basal plane dislocations in this manner, and feed-backing the results, the optimal growth rate at the initial stage of film formation is determined. The range of the growth rate at the initial stage of film formation is 5 μm/h or more and 80 μm/h or less.

While repeating the first procedure to the third procedure, optimal film formation conditions are determined by a preliminary examination. Then, the SiC epitaxial layer 20 is formed under optimal film formation conditions determined by the preliminary examination, and thus the SiC epitaxial wafer 100 with few first basal plane dislocations can be produced.

In the SiC epitaxial wafer 100 according to the present embodiment, the number of first basal plane dislocations is small. First basal plane dislocations can be one cause of stacking faults when a high voltage is applied to a device. Therefore, the SiC epitaxial wafer 100 with few first basal plane dislocations has high quality, and defects are less likely to occur in devices using the SiC epitaxial wafer 100.

While preferable embodiments of the present invention have been described above in detail, the present invention is not limited to these specific embodiments, and various modifications and alternations can be made in a range within the spirit and scope of the present invention described in the scope of the claims.

### EXAMPLES

### Example 1

A SiC wafer with a diameter of 150 mm (6-inch) and an offset angle of 4° was prepared, and under film formation conditions optimized in advance, the buffer layer 21 with a thickness of 0.5 μm was formed on the SiC wafer 10. The impurity concentration of the buffer layer 21 was 1.0×10¹⁸ cm⁻³. Then, the buffer layer 21 produced by the above procedure was measured using a mirror electronic inspection device. The number of basal plane dislocations in the buffer layer 21 of Example 1 was 0.

### Example 2

In Example 2, the buffer layer 21 was formed under the same conditions as in Example 1 except that the thickness of the buffer layer 21 was 1.0 μm. The number of basal plane dislocations in the buffer layer 21 of Example 2 was 0.

### Example 3

In Example 3, the buffer layer 21 was formed under the same conditions as in Example 1 except that the thickness of the buffer layer 21 was 1.5 μm. The number of basal plane dislocations in the buffer layer 21 of Example 3 was 3.

### Comparative Example 1

Comparative Example 1 differed from Example 1 in that the buffer layer 21 was formed without optimizing film formation conditions for the buffer layer 21. The number of basal plane dislocations in the buffer layer 21 of Comparative Example 1 was 75.

### Comparative Example 2

Comparative Example 2 differed from Example 2 in that the buffer layer 21 was formed without optimizing film formation conditions for the buffer layer 21. The number of basal plane dislocations in the buffer layer 21 of Comparative Example 2 was 49.

### Comparative Example 3

Comparative Example 3 differed from Example 3 in that the buffer layer 21 was formed without optimizing film formation conditions for the buffer layer 21. The number of basal plane dislocations in the buffer layer 21 of Comparative Example 3 was 22.

The results of Examples 1 to 3 and Comparative Examples 1 to 3 are summarized in Table 1.

TABLE 1

| | Buffer layer | Film formation | Number of basal |
|---|---|---|---|
| | thickness (μm) | conditions | plane dislocations |
| Example 1 | 0.5 | optimization | 0 |
| | | condition | |
| Example 2 | 1.0 | optimization | 0 |
| | | condition | |
| Example 3 | 1.5 | optimization | 3 |
| | | condition | |
| Comparative | 0.5 | general condition | 75 |
| Example 1 | | | |
| Comparative | 1.0 | general condition | 49 |
| Example 2 | | | |
| Comparative | 1.5 | general condition | 22 |
| Example 3 | | | |

Comparing Examples 1 to 3 and Comparative Examples 1 to 3, it was confirmed that, when film formation conditions for the SiC epitaxial layer were optimized by a preliminary examination, the number of basal plane dislocations confirmed was significantly reduced. In addition, when a device was produced using a wafer in which the number of basal plane dislocations confirmed by the measurement method was 20 or less, and a current was applied to the device, no deterioration of the device was confirmed.

### Reference Example 1

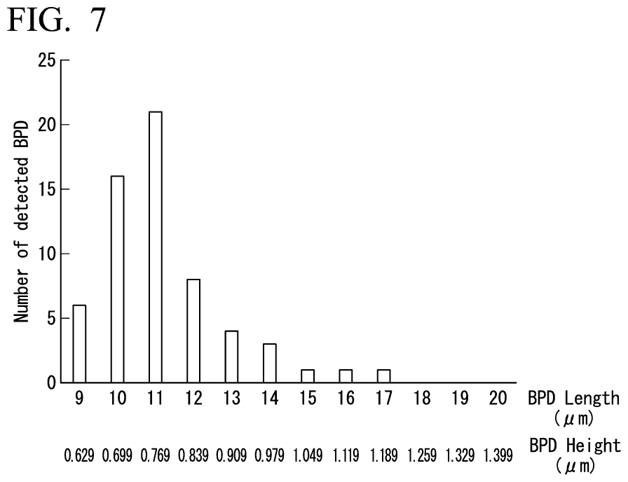

A buffer layer 21 was formed using a SiC wafer different from that of Comparative Example 2 under the same conditions as in Comparative Example 2. The number of basal plane dislocations in the buffer layer 21 was 61. Then, the length of each basal plane dislocation was measured, and the height of the basal plane dislocation was determined. FIG. 7 shows the measurement results of basal plane dislocations of Reference Example 1. As shown in FIG. 7, most of the basal plane dislocations had a height of 1 μm or less, and when a mirror electronic inspection device was used, such basal plane dislocations with short lengths could also be detected.

### Reference Example 2

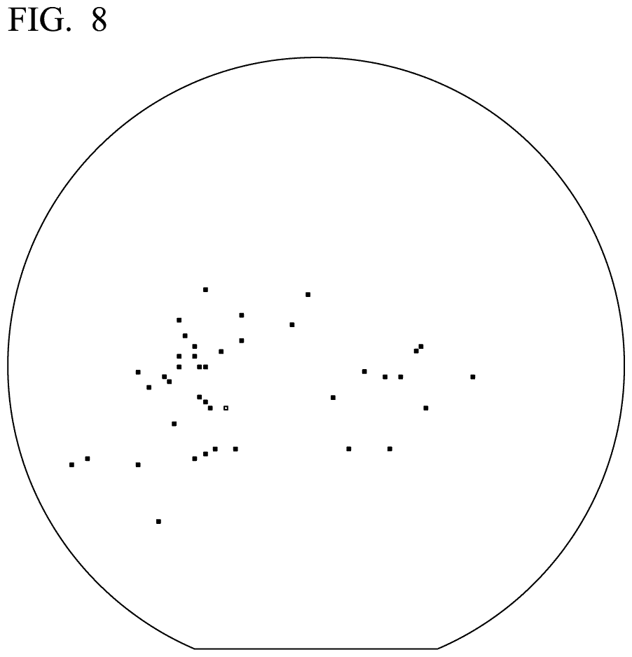

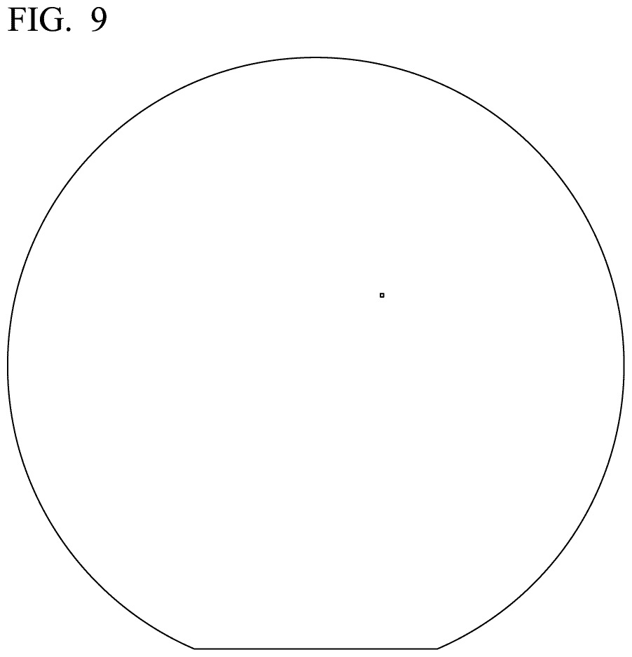

In Reference Example 2, a drift layer 22 with a thickness of 5 μm was formed on the buffer layer 21 formed under conditions of Comparative Example 2. FIG. 8 is a diagram showing the distribution of basal plane dislocations in a SiC epitaxial wafer of Comparative Example 2. FIG. 9 is a diagram showing the distribution of basal plane dislocations in a SiC epitaxial wafer of Reference Example 1.

As shown in FIG. 8 and FIG. 9, most of the basal plane dislocations that had been confirmed in the buffer layer 21 could no longer be confirmed by forming the drift layer 22. This is thought to have been caused by the fact that basal plane dislocations were converted into threading edge dislocations at the interface between the buffer layer 21 and the drift layer 22.

### Reference Example 3

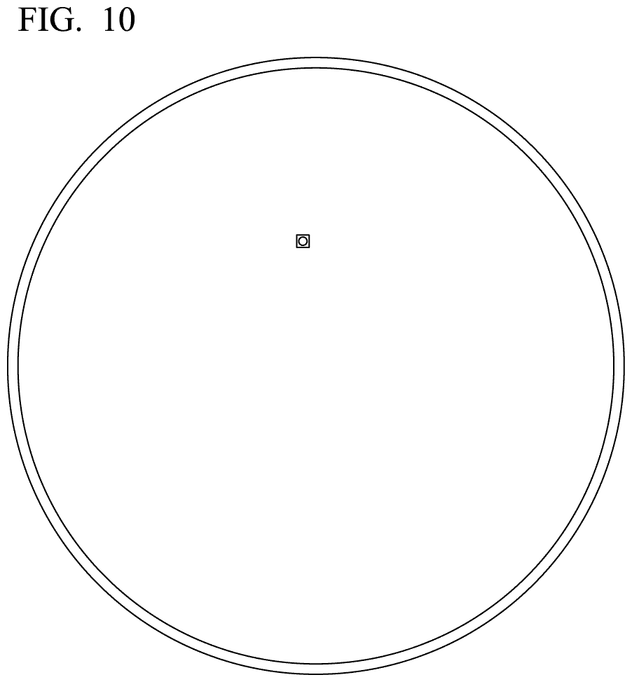

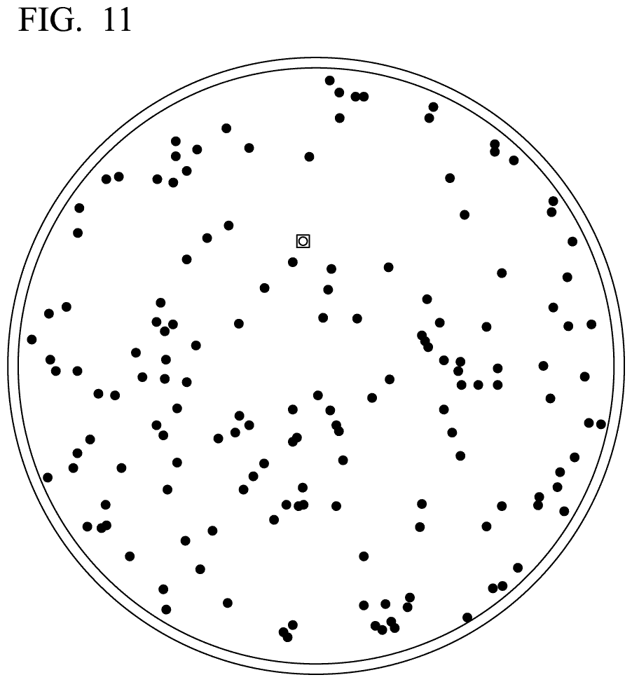

In Reference Example 3, the SiC epitaxial wafer of Comparative Example 2 was inspected using the PL method. FIG. 10 is a diagram showing the distribution of basal plane dislocations in a SiC epitaxial wafer measured by a photoluminescence method using an NIR filter. FIG. 11 is a diagram showing the distribution of basal plane dislocations in a SiC epitaxial wafer measured by a photoluminescence method using an NUV filter.

As shown in FIG. 10, in the PL method using an NIR filter, sufficient basal plane dislocations could not be detected. This is thought to have been caused by the fact that, in the buffer layer 21 with a high impurity concentration, the surrounding light emission was stronger than light emission of basal plane dislocations, and it was not possible to identify basal plane dislocations in the buffer layer 21. On the other hand, as shown in FIG. 11, in the PL method using an NUV filter, defects or dislocations other than the basal plane dislocations were also detected. This is thought to have been caused by the fact that, by the PL method, it was difficult to distinguish basal plane dislocations with short lengths from defects or dislocations other than the basal plane dislocations, and defects or dislocations other than the basal plane dislocations were misidentified as basal plane dislocations with short lengths.

### Reference Example 4

In Reference Example 4, for a SiC epitaxial wafer having the same structure as that of Reference Example 2, when the density of basal plane dislocations on the entire surface of the wafer on the surface of the drift layer was measured using the PL method using an NIR filter, it was 4.4 cm⁻². When the wafer was measured using a mirror electronic inspection device using an area in a range of 0.15% to 0.85% of the entire SiC epitaxial wafer as an inspection range, the basal plane dislocation density was 4.0 cm⁻², and it was confirmed that the values almost matched.

### EXPLANATION OF REFERENCES

10 SiC wafer
20 SiC epitaxial layer
21 Buffer layer
22 Drift layer
100 SiC epitaxial wafer
1A, 1B, 1C, 1D Basal plane dislocation
2A, 2B, 2C Threading edge dislocation
A1 Measurement region
A2 Exclusion region
A3, A4 Area
P1 Imaging point

What is claimed is:

1. A SiC epitaxial wafer, comprising:
a SiC wafer; and
a SiC epitaxial layer on one surface of the SiC wafer,
wherein the SiC epitaxial layer has a buffer layer and a drift layer,
wherein the buffer layer is disposed between the drift layer and the SiC wafer, and has a higher impurity concentration than the drift layer,
wherein, among basal plane dislocations, the number of first basal plane dislocations having a height of 1 μm or less in a thickness direction from an interface between the SiC wafer and the SiC epitaxial layer is 20 or less, and
the SiC epitaxial wafer has a diameter of 149 mm or more.

2. A SiC epitaxial wafer, comprising:
a SiC wafer; and
a SiC epitaxial layer on one surface of the SiC wafer,
wherein the SiC epitaxial layer has a buffer layer and a drift layer,
wherein the buffer layer is disposed between the drift layer and the SiC wafer, and has a higher impurity concentration than the drift layer,
wherein, among basal plane dislocations, the number of first basal plane dislocations having a height of 1 μm or less in a thickness direction from an interface between the SiC wafer and the SiC epitaxial layer is 35 or less, and
wherein the SiC epitaxial wafer has a diameter of 199 mm or more.

3. The SiC epitaxial wafer according to claim 1,
wherein, when a measurement region excluding an exclusion region within 5 mm from the outer circumference of the SiC epitaxial layer is divided into 5 mm squares, the number of first basal plane dislocations is less than 3 in 98% or more of the entire divided area.

4. The SiC epitaxial wafer according to claim 2,
wherein, when a measurement region excluding an exclusion region within 5 mm from the outer circumference of the SiC epitaxial layer is divided into 5 mm squares, the number of first basal plane dislocations is less than 3 in 98% or more of the entire divided area.

5. The SiC epitaxial wafer according to claim 1,
wherein the buffer layer has an impurity concentration of 5.0×10¹⁷ cm⁻³ or more.

6. The SiC epitaxial wafer according to claim 2,
wherein the buffer layer has an impurity concentration of 5.0×10¹⁷ cm⁻³ or more.
